(19) United States
(12) Patent Application Publication
(10) Pub. No.: US 2026/0206221 A1
(43) Pub. Date: Jul. 16, 2026

(54) MEMORY DEVICE AND METHOD OF MANUFACTURING THE SAME

(71) Applicant: MACRONIX International Co., Ltd., Hsinchu (TW)

(72) Inventor: Yan-Ru Su, Chiayi County (TW)

(73) Assignee: MACRONIX International Co., Ltd., Hsinchu (TW)

(21) Appl. No.: 19/017,778

(22) Filed: Jan. 13, 2025

(51) Int. Cl. H10B 43/27; H10B 43/10

(52) U.S. Cl. CPC H10B 43/27; H10B 43/10

(57) ABSTRACT

A memory device includes a stacked structure, a vertical channel pillar, a charge storage structure, a first conductive plug, a second conductive plug, and a metal silicide layer. The stacked structure includes a plurality of insulating layers and a plurality of conductive layers that are alternately stacked. The vertical channel pillar vertically penetrates the stacked structure, in which the vertical channel pillar includes an insulating column and a channel layer surrounding the insulating column. The charge storage structure is disposed between the channel layer and the plurality of conductive layers. The first conductive plug and the second conductive plug are vertically arranged on both sides of the insulating column and connected with the channel layer. The metal silicide layer is formed on an entire top surface of the first conductive plug and an entire top surface of the second conductive plug.

### BACKGROUND

### Technical Field

The disclosure relates to a semiconductor component, and particularly relates to a memory device and a method of manufacturing the same.

### Description of Related Art

Since a non-volatile memory has the advantage that stored data does not disappear at power-off, it becomes a widely used memory for a personal computer or other electronics equipment.

Currently, the three-dimensional (3D) memory commonly used in order to further improve the integration density of memory devices. However, due to the continuous miniaturization of semiconductor components, there are still many challenges related to 3D memory.

### SUMMARY

The disclosure provides a memory device and a method of manufacturing the same, which can reduce contact resistance and increase on-state current (Iₒₙ).

In an embodiment of the disclosure, a memory device at least includes a stacked structure, a vertical channel pillar, a charge storage structure, a first conductive plug, a second conductive plug, and a metal silicide layer. The stacked structure includes insulating layers and conductive layers that are alternately stacked. The vertical channel pillar vertically penetrates the stacked structure, in which the vertical channel pillar includes an insulating column and a channel layer surrounding the insulating column. The charge storage structure is disposed between the channel layer and the conductive layer. The first conductive plug and the second conductive plug are vertically arranged on both sides of the insulating column and connected with the channel layer. The metal silicide layer is formed on the entire top surface of the first conductive plug and the entire top surface of the second conductive plug.

In an embodiment of the disclosure, a method of manufacturing a memory device includes the following steps. A stacked structure is formed, and the stacked structure includes insulating layers and sacrificial layers that are alternately stacked. A vertical channel pillar penetrating the stacked structure is formed, in which the vertical channel pillar comprises an insulating column and a channel layer surrounding the insulating column. A first conductive plug and a second conductive plug are formed on both sides of the insulating column, in which the first conductive plug and the second conductive plug are connected with the channel layer, and a metal silicide layer is formed on the entire top surface of the first conductive plug and the entire top surface of the second conductive plug. A gate replacement process is performed to replace each sacrificial layer with a charge storage structure and a conductive layer.

Based on the above, since there is metal silicide layer with low resistance on the entire top surfaces of the first conductive plug and the second conductive plug in the embodiment of the disclosure, a good interface between contacts to the first conductive plug and the second conductive plug which can lower down the contact resistance, thereby increasing the on-state current. Furthermore, the metal silicide layer can serve as a good etching stop layer during the formation of the contacts.

### BRIEF DESCRIPTION OF THE DRAWINGS

FIG. 1A is a top view of a memory device according to an embodiment of the disclosure.

FIG. 1B is a cross-sectional view taken along a line B-B′ in FIG. 1A.

FIG. 2 is a cross-sectional view of another memory device according to an embodiment of the disclosure.

FIG. 3A to FIG. 3L are cross-sectional views of the manufacturing process of a memory device according to an embodiment of the disclosure.

FIG. 4A to FIG. 4E are cross-sectional views of the manufacturing process of another memory device according to an embodiment of the disclosure.

### DESCRIPTION OF THE EMBODIMENTS

The concepts of the disclosure may be understood by referring to the following detailed description in conjunction with the accompanying drawings. Furthermore, the dimensions of each region in the drawings are not actual dimensions, and the dimensions between the section view and the top view are not drawn to scale and are for illustration only.

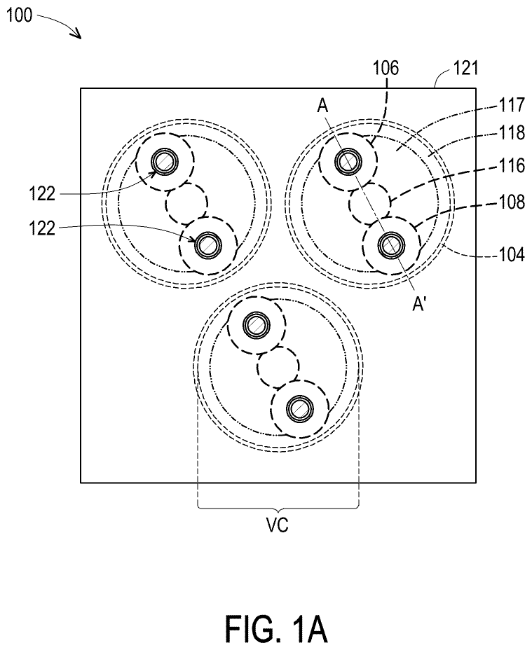

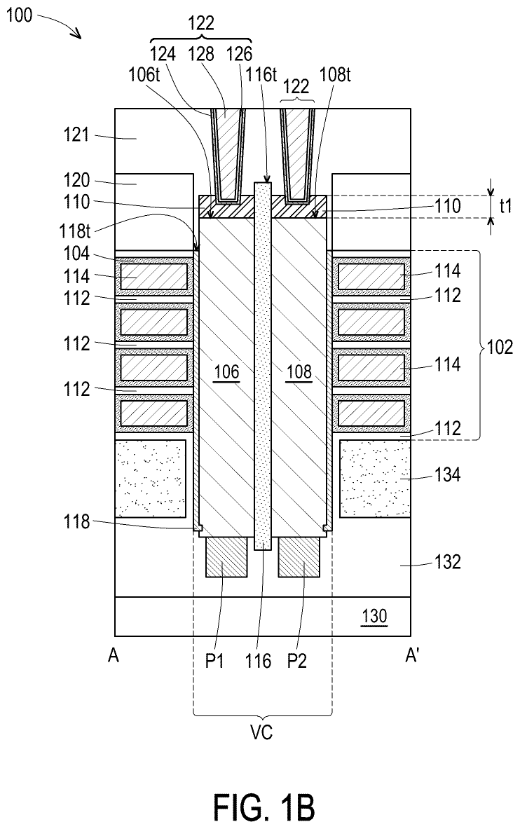

FIG. 1A is a top view of a memory device according to an embodiment of the disclosure. FIG. 1B is a cross-sectional view taken along a line B-B′ in FIG. 1A.

Referring to FIG. 1A and FIG. 1B, a memory device 100 of the embodiment at least includes a stacked structure 102, a vertical channel pillar VC, a charge storage structure 104, a first conductive plug 106, a second conductive plug 108, and a metal silicide layer 110. The stacked structure 102 includes a plurality of insulating layers 112 and a plurality of conductive layers 114 that are alternately stacked. That is, the stacked structure 102 is composed of layers of the insulating layers 112 and the conductive layers 114 between the insulating layers 112. The numbers of the insulating layers 112 and the conductive layers 114 are not limited to as shown in the drawing, and may be 8 layers, 16 layers, 32 layers, 64 layers, or more. In one embodiment, a material of the insulating layer 112 includes silicon oxide. In one embodiment, the conductive layer 114 includes, for example, a metal layer, and a material of the metal layer includes tungsten (W). In one embodiment, polysilicon is first formed at the position of each conductive layer 114 and then replaced by a metal material through through a gate replacement process. That is, the conductive layers 114 may be gate layers in the memory device 100. A vertical channel pillar VC vertically penetrates the stacked structure 102, in which the vertical channel pillar VC includes an insulating column 116 and a channel layer 118 surrounding the insulating column 116. In one embodiment, a material of the channel layer 118 includes polysilicon, but the disclosure is not limited thereto. The charge storage structure 104 is disposed between the channel layer 118 and the conductive layer 114. In one embodiment, the charge storage structure 104 is an oxide/nitride/oxide (ONO) layer, but the disclosure is not limited thereto. The first conductive plug 106 and the second conductive plug 108 are vertically arranged on both sides of the insulating column 116 and connected with the channel layer 118. In the top view of FIG. 1A, the edges of the first conductive plug 106 and the second conductive plug 108 extend toward the channel layer 118. Therefore, the channel layer 118 has a thinner portion connected to the first conductor plug 106/the second conductor plug 108, and a thicker portion not connected to the first conductor plug 106/the second conductor plug 108. In one embodiment, the first conductive plug 106 and the second conductive plug 108 may be the source and the drain of the memory device 100.

Referring to FIG. 1B, the metal silicide layer 110 is formed on the entire top surface 106t of the first conductive plug 106 and the entire top surface 108t of the second conductive plug 108. Therefore, compared with the titanium silicide merely formed at the bottom of a contact 122 in the related art, the configuration can greatly lower down the resistance of the part in contact between the first conductive plug 106 and the metal silicide layer 110, and can also greatly reduce the resistance value of the part in contact between the second conductive plug 108 and the metal silicide layer 110. Once the contact resistance here is reduced, the on-state (Iₒₙ) current can be increased. In one embodiment, the material of the insulating column 116 is, for example, silicon nitride. In one embodiment, the vertical channel pillar VC further includes a protective layer 117 as shown in FIG. 1A. In FIG. 1A, the protective layer 117 surrounds the insulating column 116 and fills the space between the channel layer 118 and both the first conductive plug 106 and the second conductive plug 108. In one embodiment, a material of the protective layer 117 is, for example, silicon oxide, but the disclosure is not limited thereto.

In one embodiment, the metal silicide layer 110 is a cobalt silicide layer or a nickel silicide layer, and a material of the first conductive plug 106 and the second conductive plug 108 is polysilicon. The formation of the metal silicide layer 110 is, for example, by depositing a metal material on polysilicon and then performing a thermal process to react metal with silicon for forming metal silicide. Therefore, a thickness t1 of the metal silicide layer 110 may be greater than 0, and may be 450 Å or less.

In one embodiment, the memory device 100 may include the contact 122 formed in the dielectric layer 121, and the contact 122 lands on the metal silicide layer 110. The contact 122 includes a titanium layer 124 and a titanium nitride layer 126 as a barrier layer, and the titanium layer 124 is in direct contact with the metal silicide layer 110. A conductive metal layer 128 in the contact 122 may be copper or tungsten, but the disclosure is not limited thereto. The manufacturing process in the related art is to react the titanium layer 124 at the bottom of the contact 122 directly with polysilicon (i.e. the first conductive plug 106 and the second conductive plug 108) to form titanium silicide, so the titanium layer 124 does not remain at the bottom of the contact 122. However, in the embodiment, the titanium layer 124 with low resistance value still remains, so the contact resistance between the contact 122 to the metal silicide layer 110 is also reduced. In one embodiment, the top surface 116t of the insulating column 116 is higher than the top surface of the metal silicide layer 110, which is beneficial to electrically isolating the first conductive plug 106 and the second conductive plug 108. In the embodiment, the metal silicide layer 110 is in noncontact with the charge storage structure 104.

Referring to FIG. 1B still, below the stacked structure 102, there is further a substrate 130, a dielectric layer 132 formed on the substrate 130, and both a polysilicon layer P1 and a polysilicon layer P2 formed in the dielectric layer 132, but the disclosure is not limited thereto. In one embodiment, the polysilicon layer P1 and the polysilicon layer P2 may have the same material, such as doped or undoped polysilicon material. For example, the polysilicon layer P1 and the polysilicon layer P2 may be undoped polysilicon layers. The polysilicon layer P1 may be used as an etching stop layer during the formation of the first conductive plug 106, and the polysilicon layer P2 may be used as an etching stop layer during the formation of the second conductive plug 108 to avoid over-etching. Between the stacked structure 102 and both the polysilicon layers P1 to P2, there may be a stop layer 134. In one embodiment, the material of the stop layer 134 includes doped or undoped polysilicon material. For example, the stop layer 134 may be a P-type doped (P+) polysilicon layer. In one embodiment, the stop layer 134 may be used as an etching stop layer during formation of the vertical channel pillar VC to avoid over-etching. In one embodiment, the dielectric layer 132 is, for example, a silicon oxide layer.

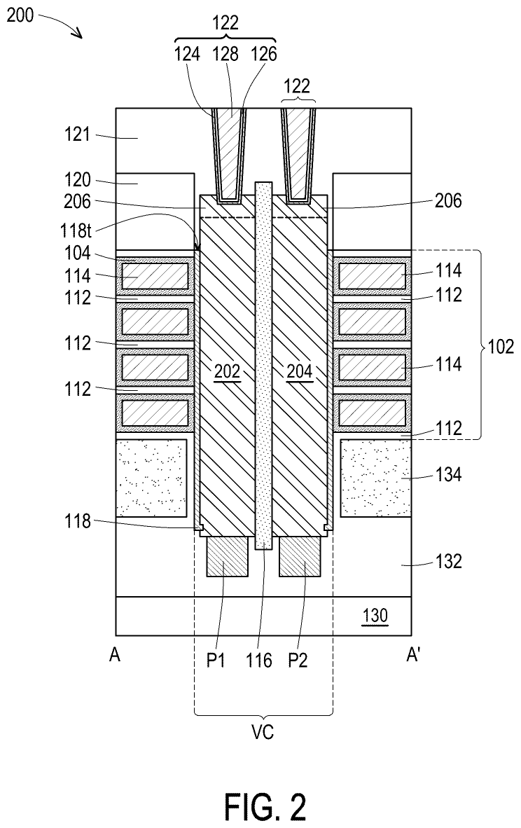

FIG. 2 is a cross-sectional view of another memory device according to an embodiment of the disclosure, in which the same reference numbers or letters as in the previous embodiment are used to represent the same or similar parts and components, and for the relevant content of the same or similar parts and components, reference may be made to the content of the previous embodiment, so details will not be repeated here.

Referring to FIG. 2, the main difference between a memory device 200 of the embodiment and the memory device 100 of the previous embodiment is the material of a first conductive plug 202 and a second conductive plug 204. The material of the first conductive plug 202 and the second conductive plug 204 is tungsten silicide, and a metal silicide layer 206 is also a tungsten silicide layer. Therefore, the first conductive plug 202 and the metal silicide layer 206 thereon may be continuously formed using the same process, and the second conductive plug 204 and the metal silicide layer 206 thereon may be continuously formed using the same process. Accordingly, the first conductive plug 202 and the metal silicide layer 206 thereon may be regarded as a homogeneous tungsten silicide column, and the second conductive plug 204 and the metal silicide layer 206 thereon may be regarded as another homogeneous tungsten silicide column.

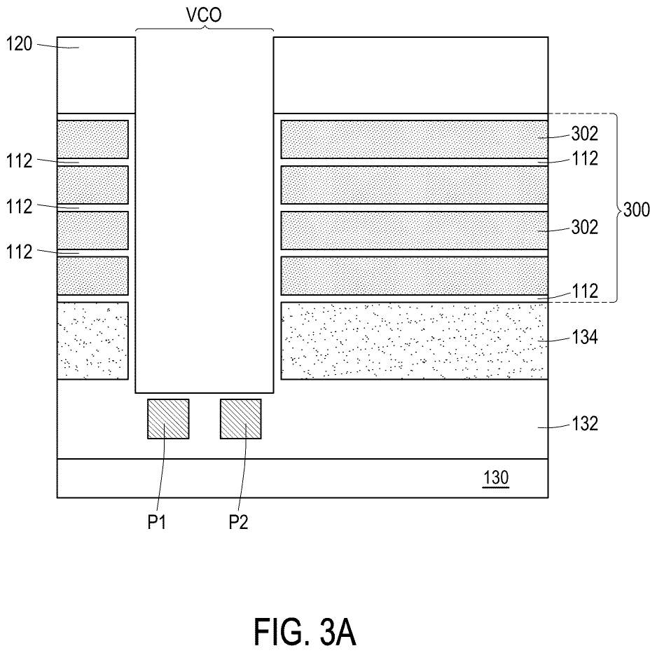

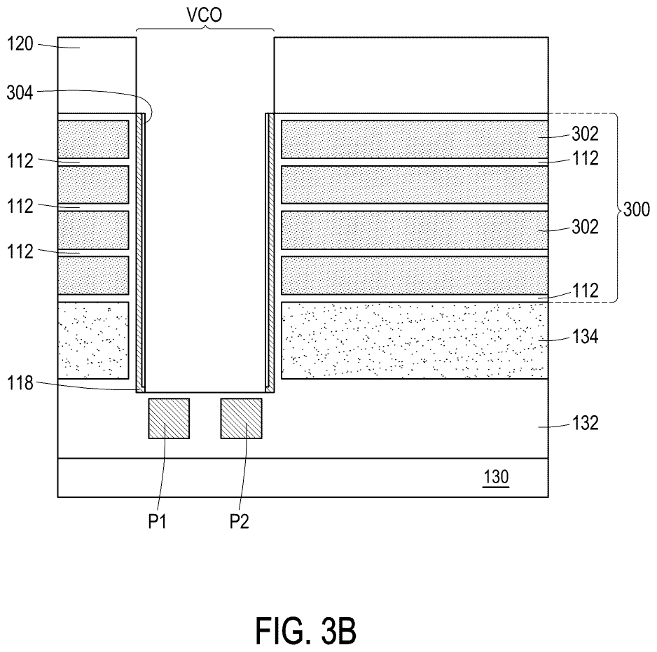

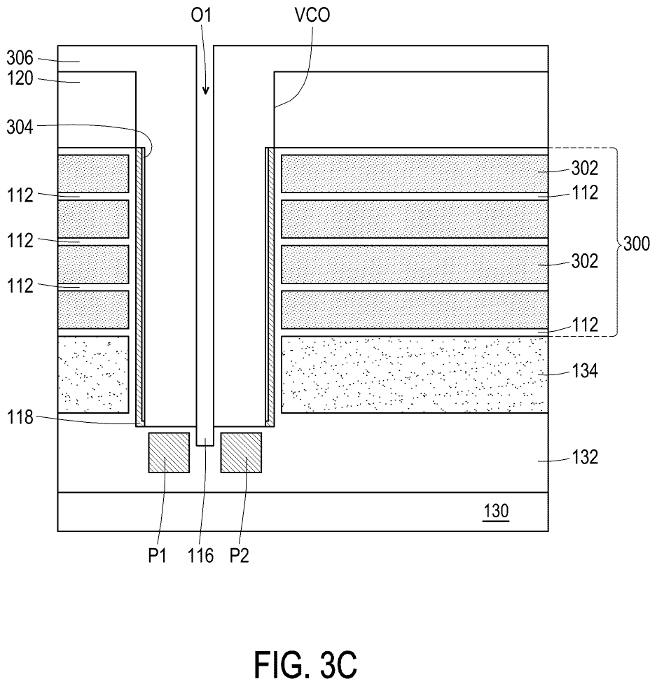

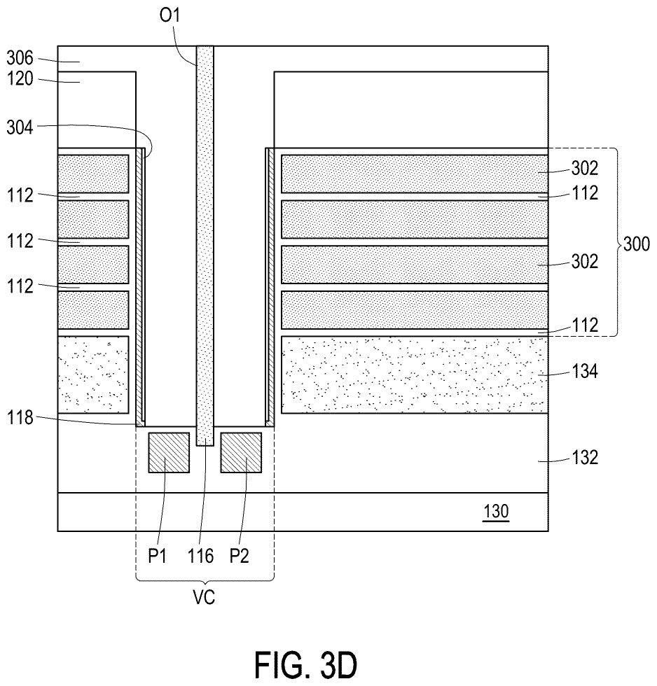

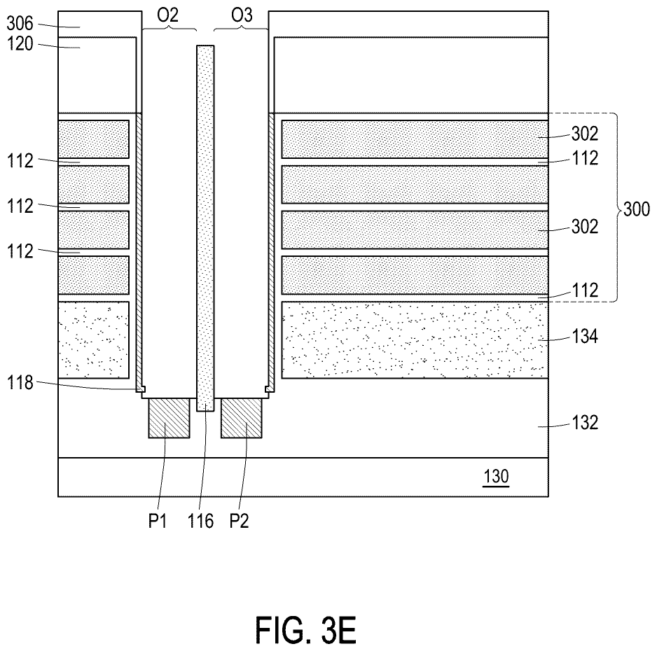

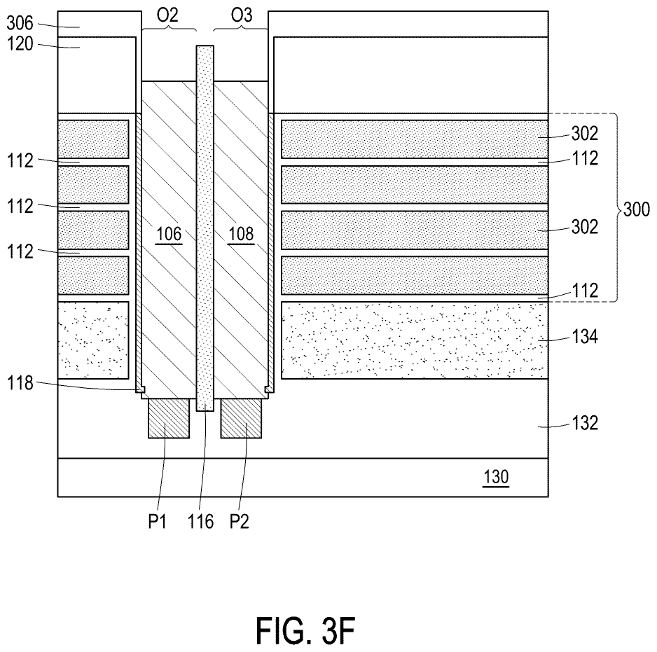

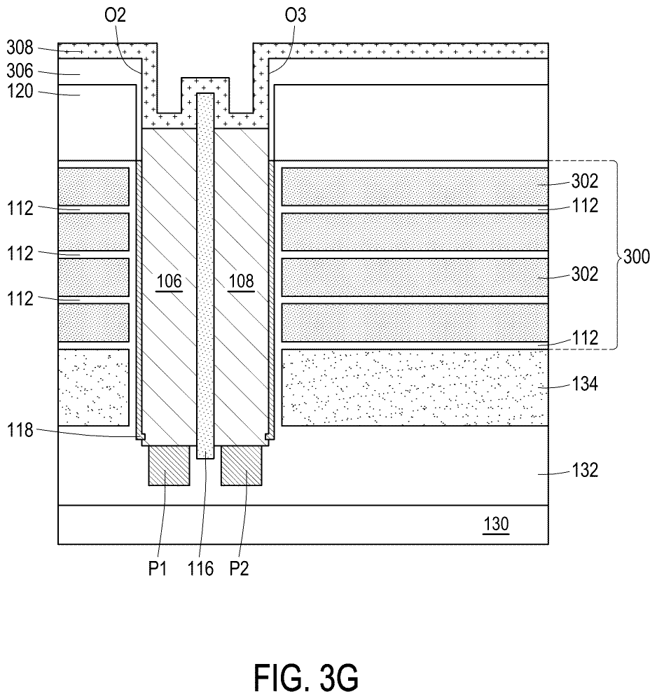

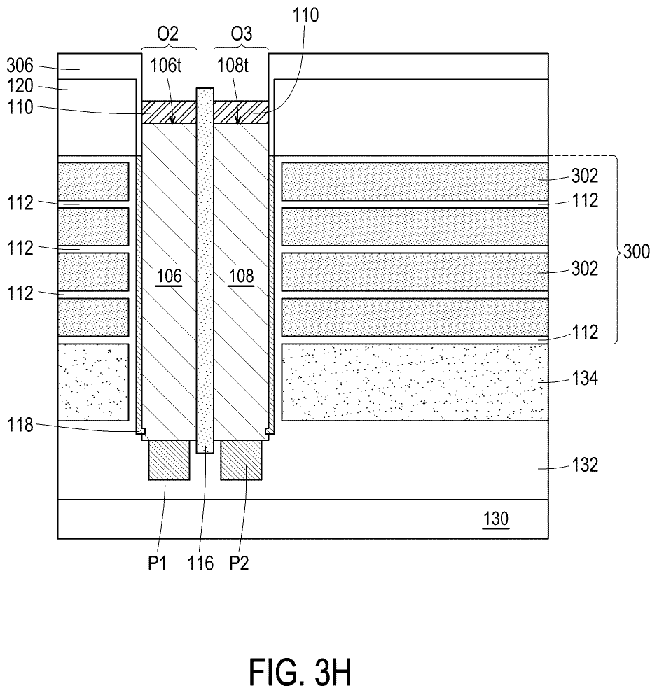

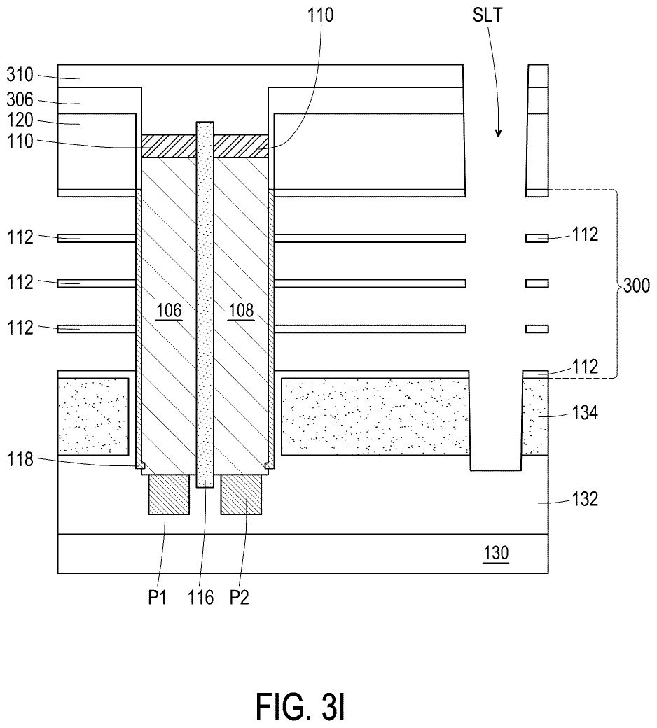

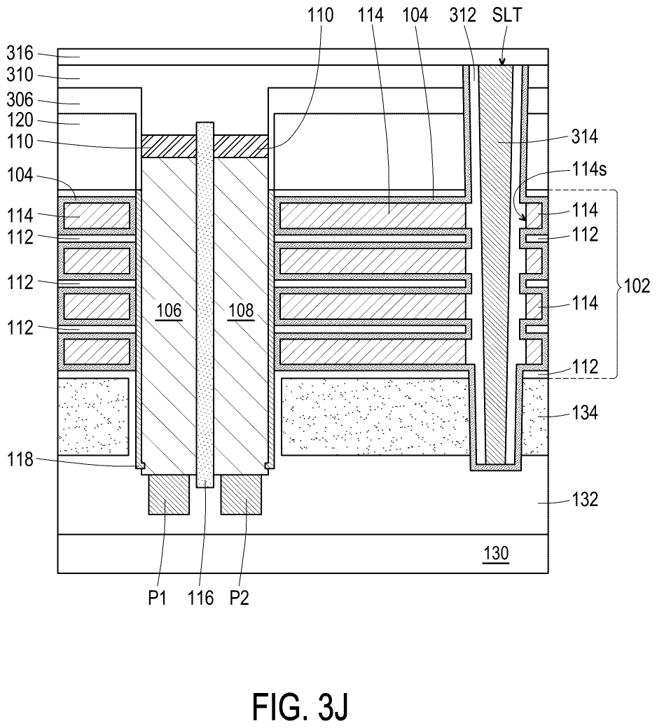

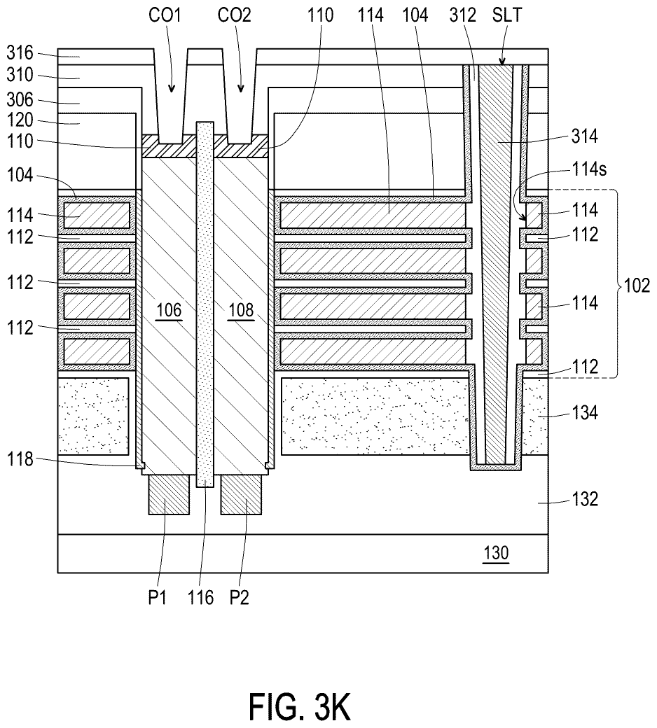

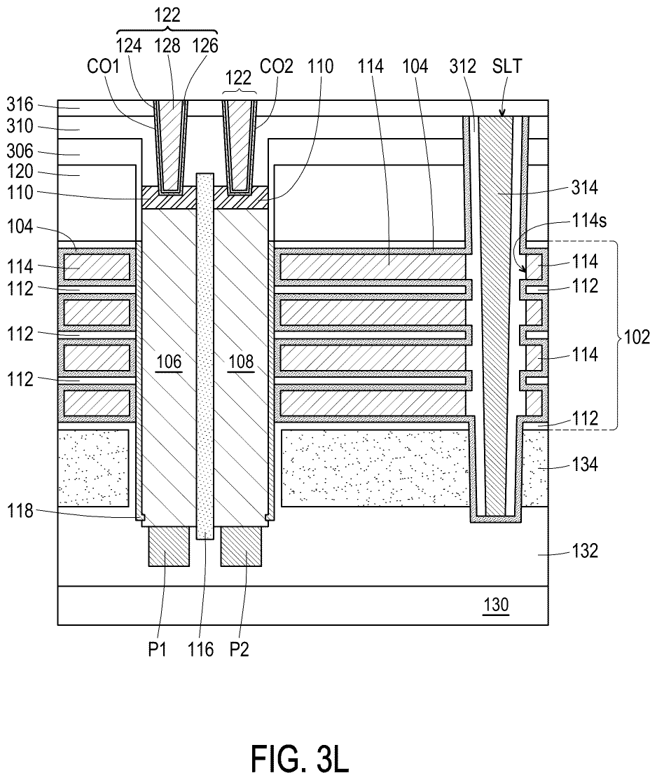

FIG. 3A to FIG. 3L are cross-sectional views of the manufacturing process of a memory device according to an embodiment of the disclosure, in which the same reference numbers or letters as in FIG. 1B are used to represent the same or similar parts, structures, or dimensional definitions, and for descriptions of the same parts, structures, or dimensional definitions, reference may be made to the relevant descriptions in FIG. 1B, so details will not be repeated here.

Referring to FIG. 3A, before forming a stacked structure 300, the dielectric layer 132 may be formed on the substrate 130, and then the polysilicon layer P1 and the polysilicon layer P2 may be formed in the dielectric layer 132. In one embodiment, the substrate 130 is, for example, a semiconductor substrate (such as silicon substrate), a semiconductor compound substrate, or a semiconductor substrate on an insulating layer (semiconductor over insulator, SOI). As for the method of forming the polysilicon layer P1 and the polysilicon layer P2, for example but not limited to the following: forming openings in the dielectric layer 132; forming polysilicon material in the openings; performing a planarization process on the polysilicon material; and forming dielectric material to cover the polysilicon material. Afterward, the stop layer 134 is formed on the dielectric layer 132.

Then, the stacked structure 300 is formed on the stop layer 134, and the stacked structure 300 includes the plurality of insulating layers 112 and a plurality of sacrificial layers 302 that are alternately stacked. In one embodiment, the sacrificial layer 302 is, for example, polysilicon or other suitable materials. In one embodiment, the insulating layer 112 and the sacrificial layer 302 may be different dielectric materials. For example, the insulating layer 112 may be a silicon oxide layer, while the sacrificial layer 302 may be a silicon nitride layer. The numbers of the insulating layers 112 and the sacrificial layers 302 are not limited to as shown in the drawing, and may be 8 layers, 16 layers, 32 layers, 64 layers, or more. Next, a vertical channel opening VCO penetrating the stacked structure 300 is formed. The method of forming the vertical channel opening VCO is, for example, first depositing a thicker dielectric layer 120 on the stacked structure 300, then patterning the dielectric layer 120 using photolithography and etching, and etching the stacked structure 300 and the stop layer 134 using the dielectric layer 120 as a mask until stopping on the dielectric layer 132. In one embodiment, the stop layer 134 may be regarded as an etching stop layer for forming the vertical channel opening VCO to avoid over-etching.

Referring to FIG. 3B, a channel layer 118 and a gap wall 304 are sequentially formed on the sidewall of the vertical channel opening VCO. Specifically, channel material may be formed first to conformally cover the surface of the vertical channel opening VCO and extend to cover the surface of the dielectric layer 120; another dielectric material is conformally deposited on the channel material; an anisotropic etching process (such as a reactive ion etching (RIE) process) is performed to remove the dielectric material and the channel material on the surface of the dielectric layer 120 and the bottom surface of the vertical channel opening VCO, and thereby the channel layer 118 and the gap wall 304 are formed on the sidewall of the vertical channel opening VCO. In one embodiment, the material of the gap wall 304 is, for example, low temperature oxide material (LTO).

Referring to FIG. 3C, the vertical channel opening VCO is filled with a protective layer 306, and the protective layer 306 may extend to cover the dielectric layer 120. In one embodiment, the protective layer 306 includes silicon oxide, silicon nitride, silicon oxynitride, or other suitable dielectric materials. Then, a central opening O1 is formed in the protective layer 306, and the formation method thereof is, for example, patterning the protective layer 306, and etching may extend into the dielectric layer 132. Also, the position of the central opening O1 is between the polysilicon layer P1 and the polysilicon layer P2.

Referring to FIG. 3D, the insulating column 116 is formed in the protective layer 306, and the formation method thereof is, for example, first filling the central opening O1 with the material of the insulating column 116, and then removing the material outside the central opening O1. The insulating column 116 and the channel layer 118 obtained in this step, together with the protective layer 306, are the structure of the vertical channel pillar VC formed subsequently.

Referring to FIG. 3E, a first plug through hole O2 and a second plug through hole O3 are formed, and the formation method thereof is, for example, patterning the protective layer 306 to form the first plug through hole O2 and the second plug through hole O3. In one embodiment, the first plug through hole O2 penetrates the stacked structure 300 and exposes the polysilicon layer P1; and the second plug through hole O3 penetrates the stacked structure 300 and exposes the polysilicon layer P2. The polysilicon layer P1 may be regarded as the etching stop layer for forming the first plug through hole O2, while the polysilicon layer P2 may be regarded as the etching stop layer for forming the second plug through hole O3 to avoid over-etching. In addition, in the step of patterning the protective layer 306, the gap wall 304 in FIG. 3D may also be removed to expose the channel layer 118. The positions of the first plug through hole O2 and the second plug through hole O3 are the positions of the first conductive plug and the second conductive plug formed subsequently. The top of the insulating column 116 may be partially reduced during this step.

Referring to FIG. 3F, the first conductive plug 106 and the second conductive plug 108 are formed in the first plug through hole O2 and the second plug through hole O3. In the embodiment, the material of the first conductive plug 106 and the second conductive plug 108 is polysilicon, and the formation method thereof is, for example, first depositing polysilicon material to fill the first plug through hole O2 and the second plug through hole O3, and then performing a back etching to remove part of the polysilicon in the first plug through hole O2 and the second plug through hole O3, where the top of the insulating column 116 is protruded.

Referring to FIG. 3G, a metal material layer 308 is formed on the surfaces of the first conductive plug 106 and the second conductive plug 108 in the first plug through hole O2 and the second plug through hole O3, in which the metal material layer 308 is, for example, cobalt (Co) or nickel (Ni). The method of forming the metal material layer 308 is, for example, sputtering or CVD depositing a layer of metal material into the first plug through hole O2 and the second plug through hole O3, and the metal material layer 308 may cover the protective layer 306.

Referring to FIG. 3H, a thermal process is performed to react the metal material layer 308 in FIG. 3G with the material (polysilicon) of the first conductive plug 106/the second conductive plug 108 for forming the metal silicide layer 110, in which the metal silicide layer 110 may be a cobalt silicide layer or a nickel silicide layer. Afterward, an unreacted portion of the metal material layer is removed, and the metal silicide layer 110 may be formed on the entire top surface 106t of the first conductive plug 106 and the entire top surface 108t of the second conductive plug 108 in a self-aligned manner.

Referring to FIG. 3I, a gate replacement process is performed. For example, a dielectric layer 310 is first formed on the structure in FIG. 3H, and then a slit SLT penetrating from top to bottom through the dielectric layer 310, the protective layer 306, the dielectric layer 120, the stacked structure 300, the stop layer 134, and all the way down to the dielectric layer 132 is formed. Then, the sacrificial layers 302 in the stacked structure 300 are all removed until the channel layer 118 is exposed. The method of removing the sacrificial layers 302 is, for example, a wet etching to laterally remove the sacrificial layers 302 from the slit SLT.

Referring to FIG. 3J, a charge storage structure 104 is formed in the space between the insulating layer 112 and on the inner surface of the slit SLT, and a conductive layer 114 is formed therein. Then, the conductive layer 114 is etched back to retract the side surfaces 114s and expose the entire slit SLT. Next, an insulating layer 312 is formed in the slit SLT, and a polysilicon layer 314 is formed in the insulating layer 312. Then, another dielectric layer 316 is formed on the entire structure.

Referring to FIG. 3K, a contact opening CO1 and a contact opening CO2 are formed in the dielectric layer 316 and the dielectric layer 310, and the metal silicide layer 110 is exposed. In one embodiment, during the formation of the contact opening CO1 and the contact opening CO2, the metal silicide layer 110 may serve as a good etching stop layer and allow the contact opening CO1 and the contact opening CO2 to be located within the metal silicide layer 110.

Referring to FIG. 3L, a contact 122 is formed in the contact opening CO1 and the contact opening CO2, and the formation method thereof is, for example, first forming the titanium layer 124 and the titanium nitride layer 126 as the barrier layer, and then filling in the contact opening CO1 and the contact opening CO2 with the conductive metal layer 128. Therefore, the titanium layer 124 in the contact 122 is in direct contact with the metal silicide layer 110.

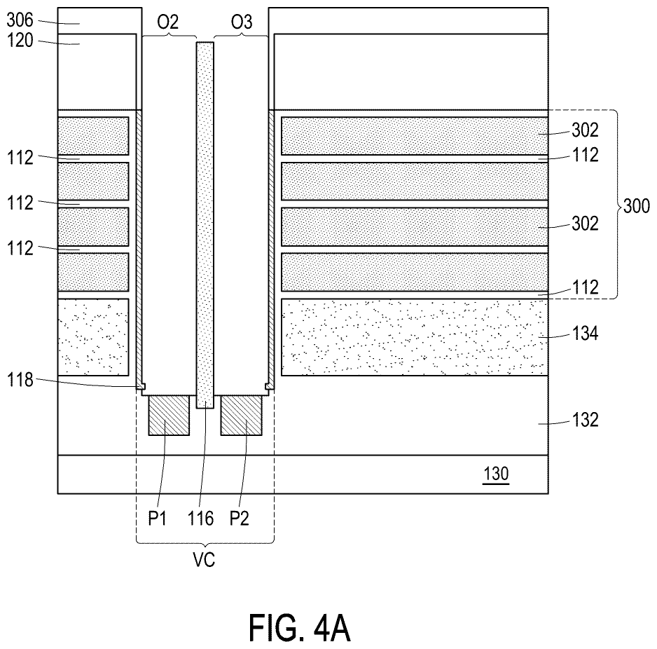

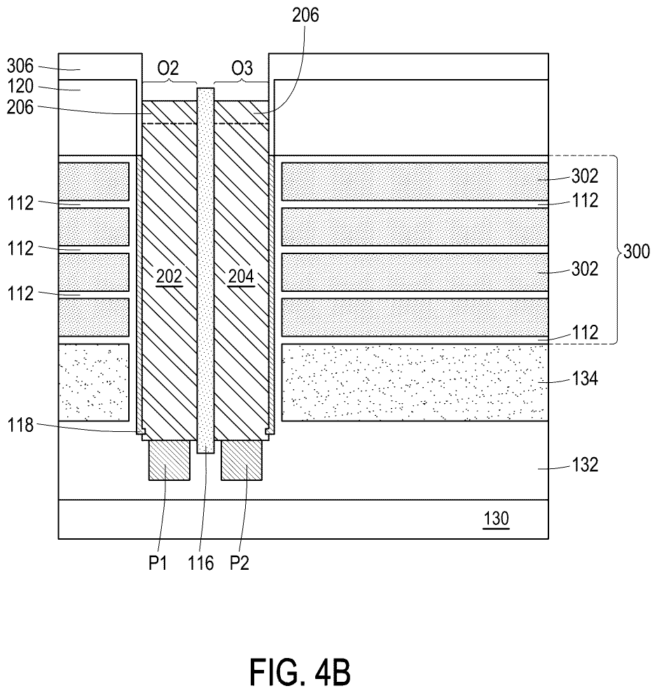

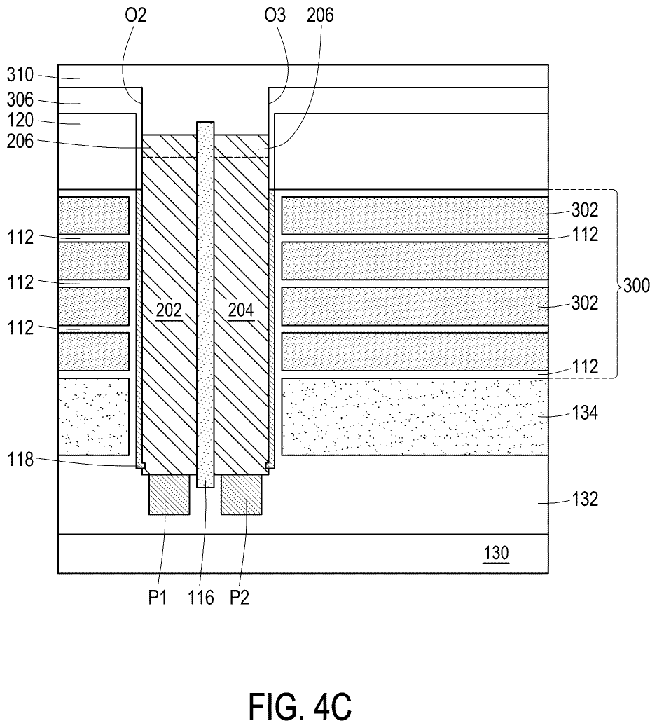

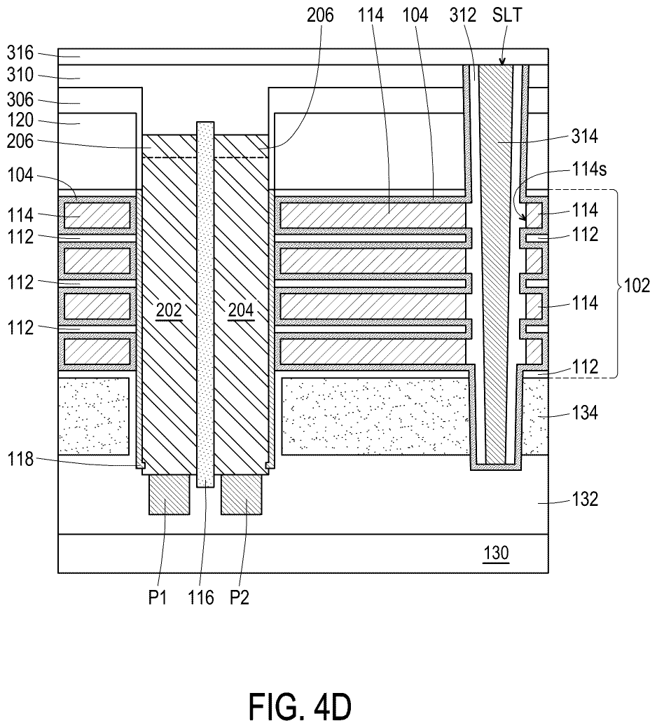

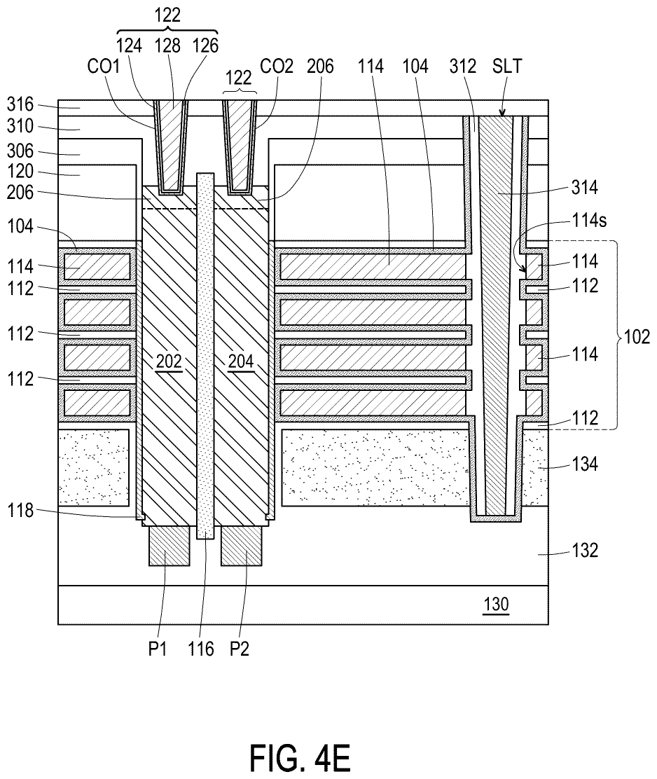

FIG. 4A to FIG. 4E are cross-sectional views of the manufacturing process of another memory device according to an embodiment of the disclosure, in which the same reference numbers or letters as in the previous embodiment are used to represent the same or similar parts, structures, or dimensional definitions, and for descriptions of the same parts, structures, or dimensional definitions, reference may be made to the relevant descriptions of the previous embodiment, so details will not be repeated here.

For the earlier steps of the manufacturing process of the embodiment, reference may be made to FIG. 3A to FIG. 3E. Therefore, FIG. 4A is essentially the same as FIG. 3E, with the first plug through hole O2 and the second plug through hole O3 penetrating the vertical channel pillar VC formed.

Referring to FIG. 4B, a metal silicide is deposited in the first plug through hole O2 and the second plug through hole O3, and then a back etching is performed on the metal silicide, in order to simultaneously form the first conductive plug 202 and the metal silicide layer 206 thereon, and to simultaneously form the second conductive plug 204 and the metal silicide layer 206 thereon. The metal silicide may be tungsten silicide (WSi₂).

Referring to FIG. 4C, the dielectric layer 310 is formed on the structure in FIG. 4B.

Afterward, the gate replacement process shown in FIG. 3I to FIG. 3J may be performed to form the charge storage structure 104 and the conductive layer 114, as shown in FIG. 4D.

Referring to FIG. 4E, as in the process in FIG. 3K to FIG. 3L, the contact 122 is formed in the contact opening CO1 and the contact opening CO2 respectively. Therefore, in direct contact with the metal silicide layer 206 is the titanium layer 124 in the contact 122.

In summary, the memory device and the method of manufacturing the same according to the embodiments of the disclosure can significantly lower down the contact resistance between the contacts to the first conductive plug and the second conductive plug in the vertical channel pillar, thereby increasing the on-state current of the memory device. Moreover, an entire layer of the metal silicide layer is between the contacts and both the first/second conductive plugs, thereby playing a good role of etching stop layer during the formation of the contacts.

What is claimed is:

1. A memory device, comprising:
a stacked structure, comprising a plurality of insulating layers and a plurality of conductive layers that are alternately stacked;
a vertical channel pillar, vertically penetrating the stacked structure, wherein the vertical channel pillar comprises an insulating column and a channel layer surrounding the insulating column;
a charge storage structure, disposed between the channel layer and the plurality of conductive layers;
a first conductive plug and a second conductive plug, vertically arranged on both sides of the insulating column and connected to the channel layer; and
a metal silicide layer formed on an entire top surface of the first conductive plug and an entire top surface of the second conductive plug.

2. The memory device according to claim 1, wherein a thickness of the metal silicide layer is 450 Å or less.

3. The memory device according to claim 1, wherein the metal silicide layer is a cobalt silicide layer, a nickel silicide layer, or a tungsten silicide layer.

4. The memory device according to claim 1, wherein the metal silicide layer is a cobalt silicide layer or a nickel silicide layer, and a material of the first conductive plug and the second conductive plug is polysilicon.

5. The memory device according to claim 1, wherein the metal silicide layer is a tungsten silicide layer, and a material of the first conductive plug and the second conductive plug is tungsten silicide.

6. The memory device according to claim 1, further comprising a contact landing on the metal silicide layer.

7. The memory device according to claim 6, wherein the contact comprises a titanium layer and a titanium nitride layer as a barrier layer, and the titanium layer is in direct contact with the metal silicide layer.

8. The memory device according to claim 1, wherein the vertical channel pillar further comprises a protective layer surrounding the insulating column and filling a space between the channel layer and both the first conductive plug and the second conductive plug.

9. The memory device according to claim 1, wherein a top surface of the insulating column is higher than a top surface of the metal silicide layer.

10. The memory device according to claim 1, wherein the metal silicide layer is in noncontact with the charge storage structure.

11. A method of manufacturing a memory device, comprising:
forming a stacked structure, wherein the stacked structure comprises a plurality of insulating layers and a plurality of sacrificial layers that are alternately stacked;
forming a vertical channel pillar penetrating the stacked structure, wherein the vertical channel pillar comprises an insulating column and a channel layer surrounding the insulating column;
forming a first conductive plug and a second conductive plug on both sides of the insulating column, wherein the first conductive plug and the second conductive plug are connected with the channel layer, and a metal silicide layer is formed on an entire top surface of the first conductive plug and on an entire top surface of the second conductive plug; and
performing a gate replacement process to replace each of the sacrificial layers with a charge storage structure and a conductive layer.

12. The method of manufacturing the memory device according to claim 11, wherein a method of forming the metal silicide layer comprises:
forming a metal material layer on the first conductive plug and the second conductive plug, wherein a material of the first conductive plug and the second conductive plug is polysilicon;
performing a thermal process to react the metal material layer with the polysilicon to form the metal silicide layer; and
removing an unreacted portion of the metal material layer.

13. The method of manufacturing the memory device according to claim 12, wherein the metal silicide layer is a cobalt silicide layer or a nickel silicide layer.

14. The method of manufacturing the memory device according to claim 11, wherein a method of forming the first conductive plug and the second conductive plug comprises:
forming a first plug through hole and a second plug through hole penetrating the vertical channel pillar;
depositing metal silicide in the first plug through hole and the second plug through hole; and
performing a back etching on the metal silicide.

15. The method of manufacturing the memory device according to claim 14, wherein a material of the first conductive plug, the second conductive plug, and the metal silicide layer is tungsten silicide.

16. The method of manufacturing the memory device according to claim 11, after performing the gate replacement process, further comprising:
forming a dielectric layer on the stacked structure and the vertical channel pillar;
forming a plurality of contact openings in the dielectric layer until exposing the metal silicide layer; and
forming a plurality of contacts in the plurality of contact openings.

17. The method of manufacturing the memory device according to claim 16, wherein a method of forming the plurality of contacts comprises:
forming a titanium layer and a titanium nitride layer as a barrier layer in the plurality of contact openings; and
filling in the plurality of contact openings with a conductive metal layer.

18. The method of manufacturing the memory device according to claim 17, wherein the conductive metal layer comprises a tungsten metal layer.

19. The method of manufacturing the memory device according to claim 11, wherein a method of forming the vertical channel pillar penetrating the stacked structure comprises:
forming a vertical channel opening penetrating the stacked structure;
forming the channel layer on a sidewall of the vertical channel opening;
filling in the vertical channel opening with a protective layer; and
forming the insulating column in the protective layer.

20. The method of manufacturing the memory device according to claim 19, wherein a material of the protective layer is silicon oxide, and a material of the insulating column is silicon nitride.
